(19) United States
(12) Patent Application Publication
(10) Pub. No.: US 2011/0139208 A1
(43) Pub. Date: Jun. 16, 2011

(54) NANOCOMPOSITE THERMOELECTRIC MATERIAL, AND THERMOELECTRIC DEVICE AND THERMOELECTRIC MODULE INCLUDING THE SAME

(75) Inventors: Kyu-hyoung LEE, Yongin-si (KR); Hyun-sik KIM, Seoul (KR); Sang-mock LEE, Yongin-si (KR); Eun-sung LEE, Seoul (KR); Sang-soo JEE, Hwaseong-si (KR)

(73) Assignee: SAMSUNG ELECTRONICS CO., LTD., Suwon-si (KR)

(21) Appl. No.: 12/833,134

(22) Filed: Jul. 9, 2010

(30) Foreign Application Priority Data
Dec. 11, 2009 (KR) 10-2009-0109174

(51) Int. Cl. H01L 35/12; C09K 5/14

(52) U.S. Cl. 136/236.1; 252/67

(57) ABSTRACT

A nanocomposite thermoelectric material, a thermoelectric element including the nanocomposite thermoelectric material, and a thermoelectric module including the thermoelectric element are disclosed herein. The nanocomposite thermoelectric material includes highly electrically conductive nano metallic particles that are uniformly dispersed in a thermoelectric material matrix. Thus, the nanocomposite thermoelectric material has high thermoelectric performance, and thus, may be used in a wide range of thermoelectric elements and thermoelectric modules.

This application claims priority to Korean Patent Application No. 10-2009-0109174, filed on Nov. 12, 2009, and all the benefits accruing therefrom under 35 U.S.C. §119, the contents of which in its entirety is herein incorporated by reference.

### BACKGROUND

1. Field

The present disclosure relates to nanocomposite thermoelectric materials, to thermoelectric elements including the nanocomposite thermoelectric materials, and to thermoelectric modules including the thermoelectric elements, and more particularly, to nanocomposite thermoelectric materials having high thermoelectric performance, to thermoelectric elements including the nanocomposite thermoelectric materials, and to thermoelectric modules including the thermoelectric elements.

2. Description of the Related Art

A thermoelectric phenomenon is a reversible, direct energy conversion from heat to electricity and vice versa, which occurs when electrons and holes move in a material. One example of the thermoelectric phenomenon includes the Peltier effect, which is used in cooling systems that operate based on temperature differences between opposing ends of a material caused when an electric current is applied thereto. Another example is the Seebeck effect, which is used in power-generation systems that operate based on an electromotive force generated due to a temperature difference between the ends of a material.

Currently, thermoelectric materials are used in active cooling systems of semiconductor equipment and electronic devices where the use of a passive cooling system proves to be inefficient. In addition, demands for thermoelectric materials in areas such as fine temperature control systems in DNA applications where conventional refrigerant gas compression systems are ineffective have increased. Thermoelectric cooling is an environmentally friendly cooling technique that does not use a refrigerant gas. Since refrigerant gases generally cause environmental problems, the use of thermoelectric cooling avoids such environmental problems and does not generate vibration and noise. If highly efficient thermoelectric cooling materials are developed, they can be used in general cooling systems such as refrigerators or air conditioners. In addition, thermoelectric materials are regarded as a novel reproducible energy source because, if thermoelectric materials are used in heat dissipating parts of vehicles' engines or industrial plants, power can be generated based on a temperature difference between the ends of a material. A thermoelectric power generation system has been already used in Mars and Saturn spacecrafts that built to explore Mars and Saturn where solar energy is not available.

The performance of thermoelectric materials is evaluated using a dimensionless figure of merit ZT defined by Equation 1:

$$ZT = \frac{{S}^{2} σ T}{k} \qquad Equation 1$$

where S is a Seebeck coefficient, σ is the electrical conductivity, T is an absolute temperature, and κ is the thermal conductivity.

As illustrated in Equation 1, an increase of ZT of a conventional thermoelectric material may be obtained by increasing the Seebeck coefficient and the electrical conductivity, that is, the power factor (S²σ) and decreasing the thermal conductivity. However, if one of the Seebeck coefficient and the electrical conductivity is increased according to the change in the concentration of carriers such as electrons or holes, the other element is reduced. In other words, the Seebeck coefficient and the electrical conductivity have a trade-off relationship, which is a major obstacle in improving the power factor.

### SUMMARY

Disclosed herein are nanocomposite thermoelectric materials having high thermoelectric performance obtained by increasing the electrical conductivity to increase a power factor while reducing the thermal conductivity.

Disclosed herein too are methods of preparing the nanocomposite thermoelectric materials.

Disclosed herein are thermoelectric elements including the nanocomposite thermoelectric materials.

Disclosed herein are thermoelectric modules including the thermoelectric elements.

Additional aspects will be set forth in part in the description which follows and, in part, will be apparent from the description, or may be learned by practice of the presented embodiments.

In an embodiment, a nanocomposite thermoelectric material includes a thermoelectric material matrix including a thermoelectric material; and nano metallic particles that have higher electrical conductivity than the thermoelectric material and which are bonded to and dispersed in the thermoelectric material.

The thermoelectric material of the thermoelectric material matrix may include a bismuth (Bi)-tellurium (Te) based alloy thermoelectric material.

The thermoelectric material of the thermoelectric material matrix may include a compound represented by Formula 1 below:

(A₁₋ₐA′ₐ)₂(B_{1-b}B′_{b})₃ <Formula 1>

where A and A′ are different from each other, A is an element of Group 15, A′ includes at least one element selected from the group consisting of elements of Group 13, Group 14, and Group 15, rare-earth elements, and transition metals; B and B′ are different from each other, B is an element of Group 16, B′ includes at least one element selected from the group consisting of elements of Group 14, Group 15, and Group 16; 0≦a<1; and 0≦b<1.

In one embodiment, a method of preparing a nanocomposite thermoelectric material includes mixing a thermoelectric material powder with a precursor powder of a metal that has higher electrical conductivity than the thermoelectric material powder; heating the mixture to obtain nanogranules in which nano metallic particles are bonded to the thermoelectric material powder; and pressure-sintering the nanogranules.

In another embodiment, a thermoelectric element includes the nanocomposite thermoelectric material.

In yet another embodiment, a thermoelectric module includes the thermoelectric element.

### BRIEF DESCRIPTION OF THE DRAWINGS

These and/or other aspects will become apparent and more readily appreciated from the following description of the embodiments, taken in conjunction with the accompanying drawings of which:

FIG. 1 is a graph of a zeta potential of Bi_{0.5}Sb_{1.5}Te₃ thermoelectric alloy powder versus the pH;

FIG. 2 is a schematic view of a thermoelectric module;

FIGS. 3A and 3B are scanning electron microscope (SEM) images of a mixed powder including thermoelectric material powder and metal precursor powder used in Example 5;

FIGS. 4A and 4B are SEM images of nanogranules formed by combining thermoelectric material powder with nano metallic particles according to Example 5;

FIG. 5 is a TEM image of a nanocomposite thermoelectric material prepared according to Example 5;

FIG. 6 is a graph of the electrical conductivity of thermoelectric materials prepared according to Examples 1 through 6 and Comparative Example 1 versus temperature;

FIG. 7 is a graph of the Seebeck coefficient of thermoelectric materials prepared according to Examples 1 through 6 and Comparative Example 1 versus temperature;

FIG. 8 is a graph of the power factor of thermoelectric materials prepared according to Examples 1 through 6 and Comparative Example 1 versus temperature;

FIG. 9 is a graph of the thermal conductivity of thermoelectric materials prepared according to Examples 1 through 6 and Comparative Example 1 versus temperature;

FIG. 10 is a graph of the lattice thermal conductivity of thermoelectric materials prepared according to Examples 1 through 6 and Comparative Example 1 versus temperature; and

FIG. 11 is a graph of the thermoelectric performance (ZT) of thermoelectric materials prepared according to Examples 1 through 6 and Comparative Example 1 versus temperature.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

[The above paragraph may be replaced with the following] Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

A nanocomposite thermoelectric material according to an embodiment of the present invention includes a thermoelectric material matrix including a thermoelectric material; and nano metallic particles that have higher electrical conductivity than the thermoelectric material and are bonded to and dispersed in the thermoelectric material.

In general, a simple and effective method for improving the performance of a thermoelectric material is to introduce into it a material that functions as a scattering center for phonons. The phonons provide for heat delivery into a thermoelectric material matrix. For example, the introduction of a nano-sized ceramic material is into the thermoelectric material produces a small decrease in thermal conductivity and a minor improvement in thermoelectric performance because of the non-uniform dispersion and agglomeration of the ceramic material. Among the routes to high thermoelectric performance, the low thermal conductivity approach results in a superlattice thin film. A large number of interfaces in the superlattice structure play an effective role in reducing the lattice thermal conductivity through interface phonon scattering. Hence the nanoinclusions such as the nano-sized material reduce the lattice thermal conductivity effectively, while maintaining a high power factor.

In a nanocomposite thermoelectric material, the nano metallic particles that have higher electrical conductivity than the thermoelectric material are bonded to and uniformly dispersed in the thermoelectric material. This promotes a large decrease in the thermal conductivity of the thermoelectric material while the electrical conductivity of the thermoelectric material is significantly increased. Thus, the thermoelectric material has a high thermoelectric performance.

In other words, when nano metallic particles having high electrical conductivity are introduced onto the surface of the thermoelectric material that forms a thermoelectric material matrix, the flow of photons that are responsible for heat transfer is blocked while at the same time the flow of carriers such as electrons or holes is increased according to the phonon glass electron crystal (PGEC) scheme. In addition, when the highly conductive nano metallic particles are uniformly dispersed in the thermoelectric material, the electrical conductivity of the thermoelectric material is increased, thereby increasing the value of ZT. In this regard, the bond between the thermoelectric material and the nano metallic particles may be a coulomb bond formed by charges. The improved dispersibility of nano metallic particles by the bond prevents agglomeration of nano metallic particles. Thus, it is possible to maintain the average diameter of nano metallic particles to about 50 nanometers (“nm”) or less, specifically about 40 nm or less, and more specifically about 30 nm or less, thereby reducing the thermal conductivity of the thermoelectric material. The average diameter is a number average diameter.

The thermoelectric material that forms the thermoelectric material matrix may be any bismuth-tellurium (Bi—Te) based alloy thermoelectric material that is known in the art.

The thermoelectric material that forms the thermoelectric material matrix may be a compound represented by Formula 1:

(A₁₋ₐA′ₐ)₂(B_{1-b}B′_{b})₃ <Formula 1>

where A and A′ are different from each other, A is an element of Group 15, A′ includes at least one element selected from the group consisting of elements of Group 13, Group 14, and Group 15, rare-earth elements, and transition metals; B and B′ are different from each other, B is an element of Group 16, B′ includes at least one element selected from the group consisting of elements of Group 14, Group 15, and Group 16; where a is equal to or greater than 0 and less than about 1; and where b is equal to or greater than 0 and less than about 1.

In one exemplary embodiment, in the thermoelectric material of Formula 1, A and A′ may be bismuth (Bi) and antimony (Sb), respectively, and B and B′ may be tellurium (Te) and selenium (Se), respectively.

The nano metallic particles may be any metal that has higher electrical conductivity than the thermoelectric material. For example, the nano metallic particles may include at least one type of metal selected from the group consisting of silver (Ag), aluminum (Al), copper (Cu), gold (Au), and a combination comprising at least one of the foregoing materials.

In the nanocomposite thermoelectric material, the amount of the nano metallic particles may be about 0.01 to about 0.5 parts by weight, specifically about 0.01 to about 0.35 parts by weight, based on 100 parts by weight of the thermoelectric material. When the amount of the nano metallic particles is within this range, the thermal conductivity of the thermoelectric material is efficiently decreased and the electrical conductivity of the thermoelectric material is efficiently increased.

A method of preparing the nanocomposite thermoelectric material may include mixing a thermoelectric material powder with a precursor powder of a metal that has higher electrical conductivity than the thermoelectric material powder, heating the mixture to obtain nanogranules in which nano metallic particles are bonded to the thermoelectric material powder; and pressure-sintering the nanogranules. The nano metallic powders are derived from the precursor powder of the metal.

The thermoelectric material powder may be prepared using various methods using thermoelectric material sources. Some of the preparation methods are described below, but the thermoelectric material powder may also be prepared using other methods.

Examples of a polycrystalline synthesis method include:

a method using an ampoule, in which source elements are loaded in a predetermined ratio into an ampoule made of quartz tubes or metal tube and then the ampoule is treated in a vacuum state, sealed, and heat-treated; or

an arc melting method in which source elements are loaded in a predetermined ratio into a chamber and then melted by arc discharging under an inert gas atmosphere; or

a method using a solid state reaction, in which a predetermined mixture ratio of powder sources are sufficiently mixed and then processed to obtain a hard product where the obtained hard product is heat-treated, or the mixed powder is heat treated and then processed and sintered.

Examples of a monocrystalline growth method include:

a metal flux method for crystal growth, in which a predetermined mixture ratio of source elements and another element (that provides a condition under which source elements sufficiently grow into a crystal at high temperature) are loaded into a crucible and then heat-treated at high temperature; or

a Bridgeman method for crystal growth, in which a predetermined mixture ratio of source elements are loaded into a crucible and then an end of the crucible is heated at high-temperature until source elements are melted. The high temperature region is then slowly shifted, thereby locally melting the source elements until all source elements are exposed to the high-temperature region; or

an optical floating zone method for crystal growth, in which a predetermined mixture ratio of source elements are formed into a seed rod and a feed rod, and then, light emitted from a lamp is focused on a point on the feed rod so that the source elements are locally melted at high temperature, and then the melting zone is slowly shifted upward. In one embodiment, the compositions of the seed rod and the feed rod are the same with each other in the floating zone method. In the initial stage, the seed rod (top) and the feed rod (bottom) have a very small gap between them. When heat is focused on the top of the seed rod and the bottom of the feed rod, the seed rod and the feed rod are melted and begin to connect with each other as a result of capillarity. Crystals can be grown by drawing down the connected part or the lamp is moved upward; or

a vapor transport method for crystal growth, in which a predetermined mixture ratio of source elements are loaded into a bottom portion of a quartz tube. Only the bottom portion is heated while the top portion of the quartz tube is maintained at a low temperature. Thus, when the source elements are evaporated, a solid phase reaction occurs at a low temperature.

The thermoelectric material powder may also be synthesized using a mechanical alloying method in which the source powder and steel balls are loaded into a cemented carbide vessel, and then, the cemented carbide vessel is rotated, thereby forming an alloy-type thermoelectric material by mechanical impact of the steel balls on the source powder.

The mixing of the thermoelectric material powder and the metal precursor powder may be performed using a mortar or a ball mill.

The metal precursor powder may be any material that provides a chemical bond between the thermoelectric material and the metal (derived from the metal precursor powder). In one embodiment, the metal precursor powder may be a metal acetate powder.

The metal acetate powder may be an acetate of a metal that has a higher electrical conductivity than the thermoelectric material of the thermoelectric material matrix, for example, Ag, Al, Cu, or Au. The metal acetate may be silver acetate [Ag(CH₃COO)], aluminum triacetate [Al(CH₃COO)₃], aluminum diacetate [HOAI(CH₃COO)₂], aluminum monoacetate [(HO)₂Al(CH₃COO)], copper(II) acetate: Cu(CH₃COO)₂, or gold(III) acetate: Au(CH₃COO)₃.

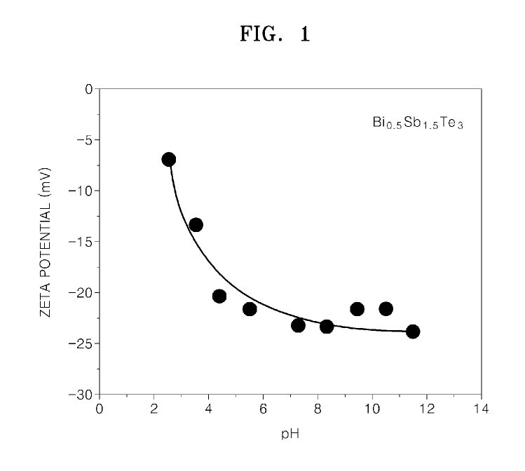

Such metal acetates are highly likely to bond to thermoelectric alloys, which, in general, have an acidic surface and do not agglomerate each other. Due to such characteristics, the metal acetates are very appropriate for the dispersion of the nano metallic particles in the thermoelectric material. In other words, the surface of the thermoelectric material has a negative (−) charge, an acetate group of the metal acetate has a negative (−) charge, and the metal has a positive (+) charge, and thus the metal may be bonded to the thermoelectric material by a coulombic force. FIG. 1 is a graph of a zeta potential versus pH of Bi_{0.5}Sb_{1.5}Te₃ thermoelectric alloy powder, which is not mixed with the metal acetate. Referring to the FIG. 1, the zeta potential of the thermoelectric alloy powder has a negative value in the entire pH range because the thermoelectric alloy powder has an acidic surface.

The mixture including the thermoelectric material powder and the metal precursor powder is heated to produce nanogranules in which nano metallic particles are uniformly dispersed in the thermoelectric material powder. In this regard, the heating may be performed at a temperature of 150° C. or higher under an inert gas atmosphere, such as argon or nitrogen gas. As a result of the heating, an organic component of the metal precursor is evaporated and nano metallic particles are bonded to the thermoelectric material powder.

The obtained nanogranules are pressure-sintered to produce a nanocomposite thermoelectric material, and the pressure-sintering may be performed at a temperature of about 300 to about 550° C. and at a pressure of about 30 to about 1000 MPa. For example, the nanogranules are loaded into a mold made of graphite and then pressure-sintered for a short time period of 10 minutes or less by plasma discharge under a vacuum, thereby producing the nanocomposite thermoelectric material. The nanocomposite thermoelectric material has a bulky phase that has a nano structure which is formed when in the powder phase.

Since the method provides a thermoelectric material having high thermoelectric performance by heating and pressure-sintering the mixed powder, it is possible to mass-produce thermoelectric elements.

A thermoelectric element according to an embodiment of the present invention is obtained by cutting and grinding the nanocomposite thermoelectric material.

The thermoelectric element may be a p-type thermoelectric element or an n-type thermoelectric element. The thermoelectric element may be a nanocomposite thermoelectric material structure having a predetermined shape, for example, a rectangular parallelopiped shape.

Meanwhile, the thermoelectric element may be connected to an electrode and used in a device that generates a cooling effect when a current is applied thereto, or a thermoelectric module for generating power due to a difference in temperature between opposing ends of the thermoelectric element.

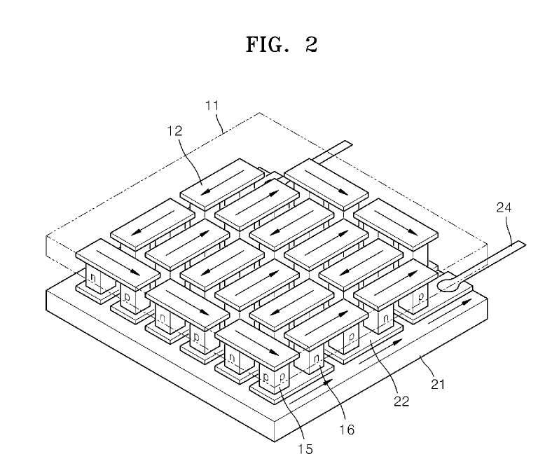

FIG. 2 is a thermoelectric module including the thermoelectric element, according to an embodiment of the present invention. Referring to FIG. 2, a top electrode 12 and a bottom electrode 22 are patterned on a top insulating substrate 11 and a bottom insulating substrate 21, respectively. The top electrode 12 and the bottom electrode 22 contact a p-type thermoelectric element 15 and an n-type thermoelectric element 16 respectively. The top electrode 12 and the bottom electrode 22 are connected to the outside by a lead electrode 24.

The top and bottom insulating substrates 11 and 21 may include gallium arsenic (GaAs), sapphire, silicon, Pyrex, quartz, or a combination comprising at least one of the foregoing insulating materials. The top and bottom electrodes 12 and 22 may include aluminum, nickel, gold, or titanium, and may have various sizes depending upon the application. The top and bottom electrodes 12 and 22 may be formed with various known patterning methods, such as a lift-off semiconductor process, a deposition method, or a photolithography method.

The thermoelectric module may be, for example, a thermoelectric cooling system or a thermoelectric power generation system. The thermoelectric cooling system may be a micro-cooling system, a generally used cooling device, an air conditioner, or a waste heat power generation system, but is not limited thereto. The structure and manufacturing method of the thermoelectric cooling system are well known in the art and thus, will not be described in detail herein. Since the thermoelectric module shows higher thermoelectric performance than conventionally available thermoelectric materials at a temperature of 100° C. or higher, the thermoelectric module may be more usefully used for cooling devices that dissipate a great amount of heat, such as electronic devices or for low-temperature thermoelectric power generation using a heat source having a temperature of 250° C. or lower.

One or more embodiments of the present invention will be described in further detail with reference to the following examples. These examples are for illustrative purposes only and are not intended to limit the scope of the one or more embodiments of the present invention.

### EXAMPLE 1

Bi_{0.5}Sb_{1.5}Te₃ powder, which is a p-type matrix material, was synthesized using an attrition mill that is used for mechanical alloying. 3.12 grams (“g”) of Bi, 5.45 g of Sb, and 11.43 g of Te, which are source elements, and steel balls having a diameter of 5 millimeter (“mm”) were loaded into a cemented carbide jar and Ar or N₂ gas was provided thereto to prevent oxidation of the source elements. In this regard, the weight of the steel balls was 20 times greater than the total weight of all the source elements. An impeller formed of cemented carbide was rotated in the cemented carbide jar at a speed of 500 revolutions per minute (“rpm”). The oxidation of the source elements caused by heat generated while rotating the impeller was prevented by providing cooling water to the outside of the cemented carbide jar.

0.02 g of silver acetate was added to 20 g of the prepared Bi_{0.5}Sb_{1.5}Te₃ powder (the amount of silver acetate was 0.1 parts by weight per 100 parts by weight of Bi_{0.5}Sb_{1.5}Te₃ powder) and then, the mixture was dry-mixed using a ball mill for about 10 minutes.

The resultant mixed powder was heated at a temperature of 300° C. for 3 hours under a nitrogen gas atmosphere, thereby obtaining nanogranules. The nanogranules were loaded in a mold made of graphite and then hot-pressed under a vacuum (10⁻² torr or less) at a pressure of 70 megapascals (“MPa”) and at a temperature of 380° C., thereby obtaining a nanocomposite thermoelectric material.

### EXAMPLE 2

A nanocomposite thermoelectric material was obtained in the same manner as in Example 1, except that the amount of silver acetate was 0.03 g instead of 0.02 g (the amount of silver acetate was 0.15 parts by weight per 100 parts by weight of Bi_{0.5}Sb_{1.5}Te₃ powder).

### EXAMPLE 3

A nanocomposite thermoelectric material was obtained in the same manner as in Example 1, except that the amount of silver acetate was 0.04 g instead of 0.02 g (the amount of silver acetate was 0.2 parts by weight per 100 parts by weight of Bi_{0.5}Sb_{1.5}Te₃ powder).

### EXAMPLE 4

A nanocomposite thermoelectric material was obtained in the same manner as in Example 1, except that 0.02 g of copper (II) acetate was used instead of the silver acetate (0.1 parts by weight of copper (II) acetate per 100 parts by weight of Bi_{0.5}Sb_{1.5}Te₃ powder).

### EXAMPLE 5

A nanocomposite thermoelectric material was obtained in the same manner as in Example 1, except that 0.03 g of copper (II) acetate was used instead of the silver acetate (0.15 parts by weight of copper (II) acetate per 100 parts by weight of Bi_{0.5}Sb_{1.5}Te₃ powder).

### EXAMPLE 6

A nanocomposite thermoelectric material was obtained in the same manner as in Example 1, except that 0.04 g of copper (II) acetate was used instead of the silver acetate (0.2 parts by weight of copper (II) acetate per 100 parts by weight of Bi_{0.5}Sb_{1.5}Te₃ powder).

### Comparative Example 1

Bi_{0.5}Sb_{1.5}Te₃ powder, which is a p-type matrix material, was synthesized using an attrition mill that is used for mechanical alloying. In detail, 3.12 g of Bi, 5.45 g of Sb, and 11.43 g of Te, which are source elements, and steel balls having a diameter of 5 mm were loaded into a cemented carbide jar and Ar or N₂ gas was provided thereto to prevent oxidation of the source elements. The weight of the steel balls was 20 times greater than the total weight of all the source elements. An impeller formed of cemented carbide was rotated in the cemented carbide jar at a speed of 500 rpm. The oxidation of the source elements caused by heat generated while rotating the impeller was prevented by providing cooling water to the outside of the cemented carbide jar.

20 g of the prepared Bi_{0.5}Sb_{1.5}Te₃ powder was loaded in a mold made of graphite and then hot-pressed under a vacuum (10⁻² torr or less) at a pressure of 70 MPa and at a temperature of 380° C., thereby obtaining a thermoelectric material.

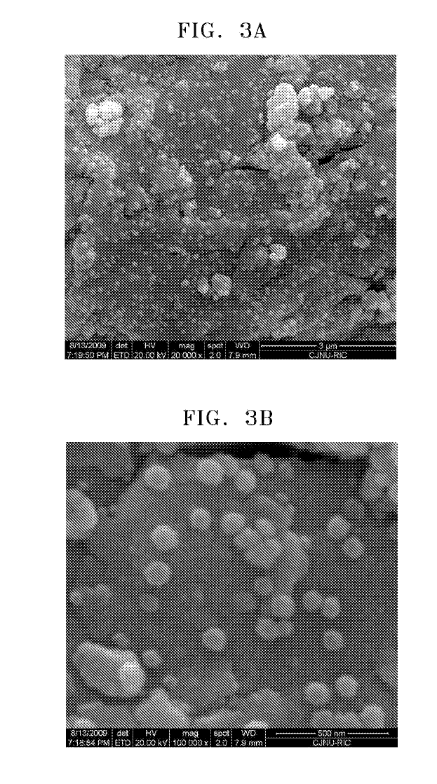

FIGS. 3A and 3B are scanning electron microscope (“SEM”) images of a mixed powder including the thermoelectric material powder and the metal precursor powder used in Example 5. Referring to FIGS. 3A and 3B, it can be seen that a metal acetate powder having an average particle diameter of about 70 nm is uniformly dispersed in the Bi_{0.5}Sb_{1.5}Te₃ powder.

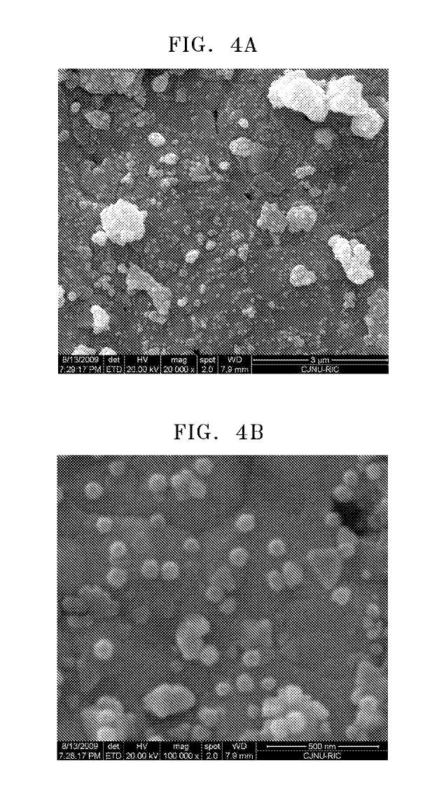

FIGS. 4A and 4B are SEM images of nanogranules formed by heating the mixed powder according to Example 5. Referring to FIGS. 4A and 4B, it can be seen that nanogranules contain copper particles having a particle size of several tens nanometers dispersed on the surface of Bi_{0.5}Sb_{1.5}Te₃ powder having a particle size of a few micrometers.

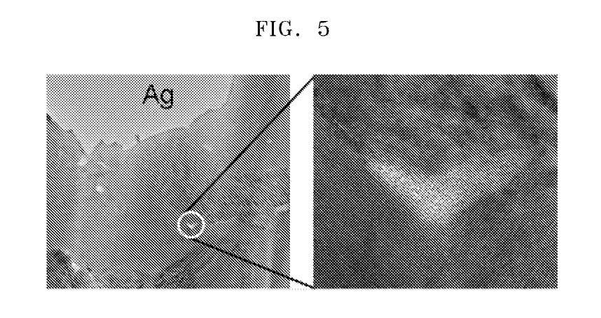

FIG. 5 is a transmission electron micrograph (“TEM”) image of the nanocomposite thermoelectric material prepared according to Example 5. Referring to FIG. 5, the nanocomposite thermoelectric material contains highly electrically conductive nano metallic particles observed at the grain boundaries of the thermoelectric material matrix.

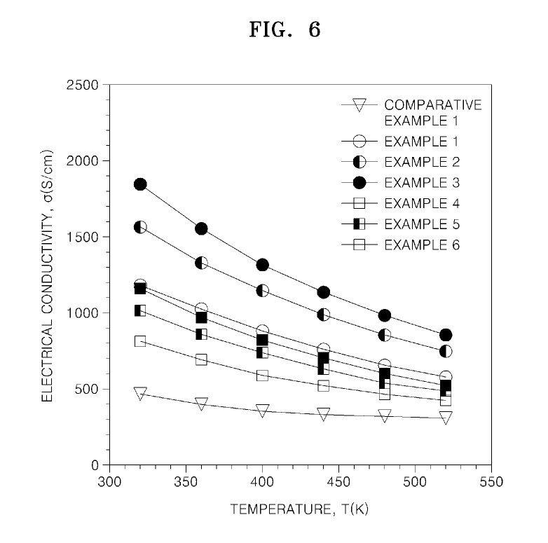

Electrical conductivity, Seebeck coefficient, power factor, thermal conductivity, lattice thermal conductivity, and thermoelectric performance (ZT) of thermoelectric elements formed using the nanocomposite thermoelectric materials prepared according to Examples 1 to 5 and Comparative Example 1 were evaluated. The evaluation results are shown in FIGS. 6 through 11. The electrical conductivity was evaluated using a direct current (“dc”) 4-probe method at a temperature of about 320 Kelvin (“K”) to about 520 K, and the Seebeck coefficient was measured using a steady-state method. The power factor, which is S²σ in Equation 1, was calculated by multiplying a square of the Seebeck coefficient by the measured electrical conductivity. The thermal conductivity was evaluated using a heat capacity measured by thermal relaxation, thermal diffusivity measured using a laser-flash method in a vacuum, and bulk density of the thermoelectric element. The lattice thermal conductivity was obtained by subtracting the thermal conductivity contribution of electrons measured using electrical conductivity (measured using a Wiedemann-Franz law and the Seebeck coefficient) from the entire thermal conductivity.

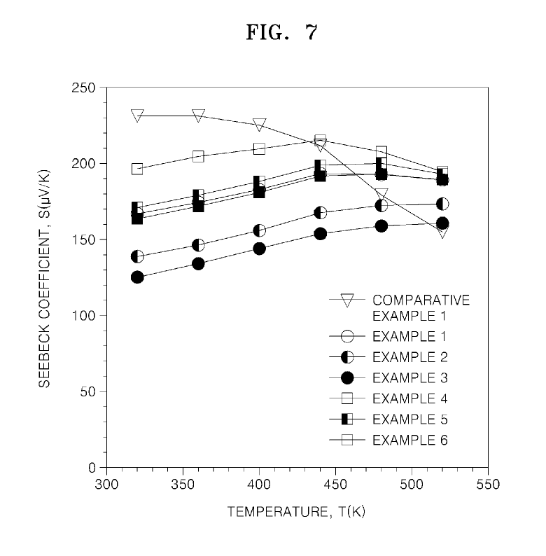

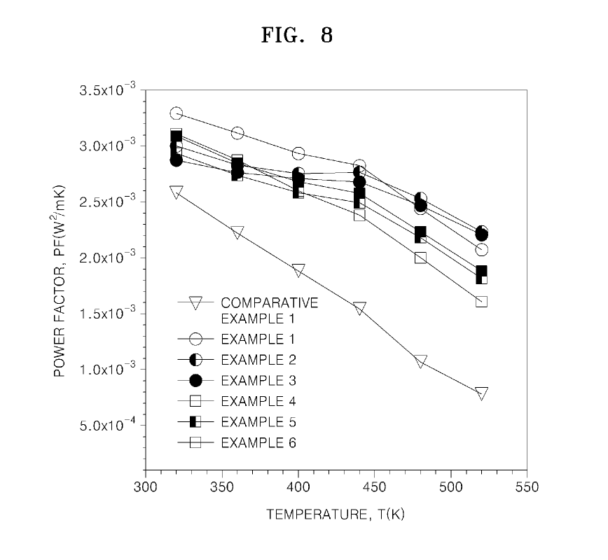

Referring to FIG. 6, the electrical conductivity of the nanocomposite thermoelectric materials prepared according to Examples 1 through 6 is higher than that of Comparative Example 1 since the concentration of carriers is increased due to the introduction of highly electrically conductive metal particles. Although the Seebeck coefficient was reduced due to the increased concentration of carriers (FIG. 7), the power factor was increased, and unlike the thermoelectric material of Comparative Example 1, the Seebeck coefficient of the nanocomposite thermoelectric materials prepared according to Examples 1 through 6 increased with the increase in temperature (FIG. 8). Even at a temperature of 440 K or more, the power factor of the nanocomposite thermoelectric materials of Examples 1 through 6 was twice or more than that of the thermoelectric material of Comparative Example 1.

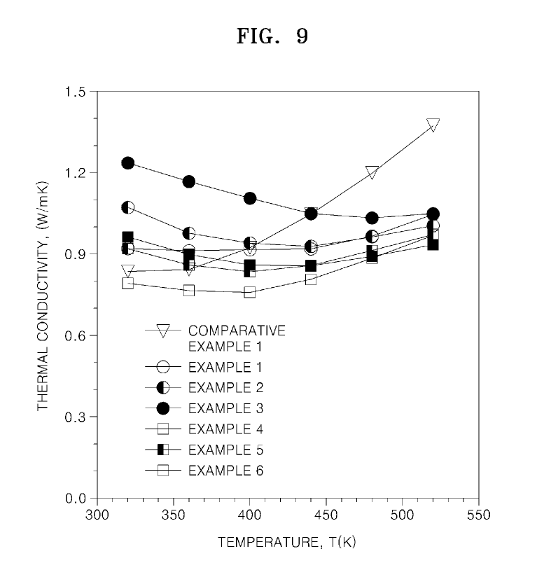

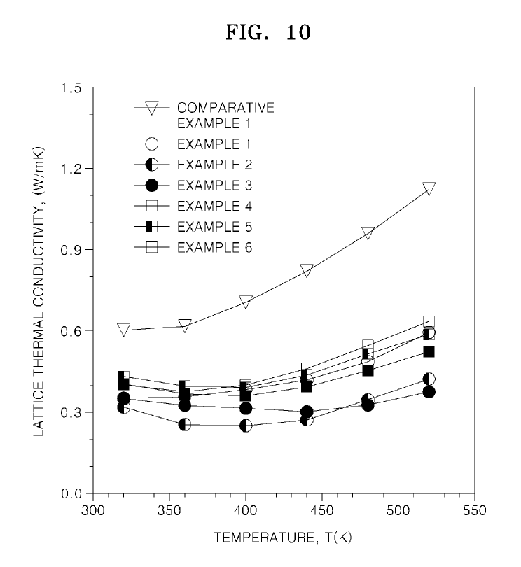

Meanwhile, as illustrated in FIG. 9, the thermal conductivity of the nanocomposite thermoelectric materials of Examples 1 to 6 is higher than the thermal conductivity of Comparative Example 1 due to the increased electrical conductivity. However, at a temperature of 400 K or higher, the thermal conductivity of the nanocomposite thermoelectric materials of Examples 1 to 6 is lower than the thermal conductivity of Comparative Example 1. As illustrated in FIG. 10, this result is due to a substantial decrease in the lattice thermal conductivity. The thermal conductivity of the nanocomposite thermoelectric material is equal to the electron thermal conductivity (thermal conductivity caused by carriers such as electrons or holes) plus the lattice thermal conductivity (thermal conductivity caused by phonon). The decrease in lattice thermal conductivity is due to the formation of PGEC by phonon scattering by nano metallic particles when the temperature is increased.

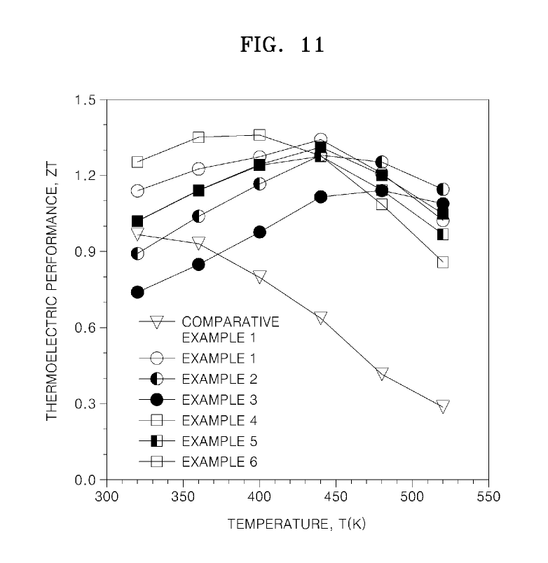

Referring to FIG. 11, the thermoelectric performance (ZT) of the nanocomposite thermoelectric materials of Examples 1 to 6 is maintained at about 1.2 at a temperature of about 320 K to about 520 K. Unlike the thermoelectric material of Comparative Example 1, where ZT is substantially decreased as the temperature is increased, the ZT of the nanocomposite thermoelectric materials of Examples 1 to 6 was either maintained at a substantially constant level or increased. For example, at a temperature of 520 K, the ZT of the nanocomposite thermoelectric material of Example 1 in which the silver nano metallic particles were mixed was 4 times higher than that of the thermoelectric material of Comparative Example 1.

As described above, nanocomposite thermoelectric materials according to the one or more of the above embodiments of the present invention have low thermal conductivity and high thermoelectric performance, and are produced using a simplified manufacturing process and thus are appropriate for mass-production.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A nanocomposite thermoelectric material comprising:
a thermoelectric material matrix comprising a thermoelectric material; and
nano metallic particles that have higher electrical conductivity than the thermoelectric material and are bonded to and dispersed in the thermoelectric material.

2. The nanocomposite thermoelectric material of claim 1, wherein the thermoelectric material of the thermoelectric material matrix comprises a bismuth-tellurium alloy thermoelectric material.

3. The nanocomposite thermoelectric material of claim 1, wherein the thermoelectric material of the thermoelectric material matrix comprises a compound represented by Formula 1:
(A₁₋ₐA′ₐ)₂(B_{1-b}B′_{b})₃ <Formula 1>
where A and A′ are different from each other, A is an element of Group 15, A′ comprises at least one element selected from the group consisting of elements of Group 13, Group 14, and Group 15; rare-earth elements, and transition metals; B and B′ are different from each other, B is an element of Group 16, B′ comprises at least one element selected from the group consisting of elements of Group 14, Group 15, and Group 16; wherein a is equal to or greater than 0 and less than about 1; and wherein b is equal to or greater than 0 and less than about 1.

4. The nanocomposite thermoelectric material of claim 1, wherein the nano metallic particles comprise at least one type of metal selected from the group consisting of silver, aluminum, copper, gold and a combination comprising at least one of the foregoing metals.

5. The nanocomposite thermoelectric material of claim 1, wherein an average particle size of the nano metallic particles is 50 nanometers or less.

6. The nanocomposite thermoelectric material of claim 1, wherein an amount of the nano metallic particles is about 0.01 to about 0.5 parts by weight based on 100 parts by weight of the thermoelectric material of the thermoelectric material matrix.

7. A method of preparing a nanocomposite thermoelectric material, the method comprising:
mixing a thermoelectric material powder with a precursor powder of a metal that has higher electrical conductivity than the thermoelectric material powder;
heating the mixture to obtain nanogranules in which nano metallic particles are bonded to the thermoelectric material powder; and
pressure-sintering the nanogranules.

8. The method of claim 7, wherein the metal precursor powder comprises a metal acetate powder.

9. The method of claim 8, wherein the metal acetate powder comprises a silver acetate, an aluminum acetate, a copper acetate, a gold acetate, or a combination comprising at least one of the foregoing metal acetates.

10. The method of claim 7, wherein the heating is performed at a temperature of 150° C. or higher under an inert gas atmosphere.

11. The method of claim 7, wherein the pressure-sintering is performed at a temperature of about 300 to about 550° C. at a pressure of about 30 to about 1000 megapascals.

12. A thermoelectric element comprising the nanocomposite thermoelectric material of claim 1.

13. A thermoelectric module comprising:
a top insulating substrate on which a top electrode is patterned;
a bottom insulating substrate on which a bottom electrode is patterned; and
a p-type thermoelectric element and an n-type thermoelectric element that contact the top electrode and the bottom electrode,
wherein the p-type thermoelectric element or the n-type thermoelectric element each comprise:
a thermoelectric material matrix comprising a thermoelectric material; and
nano metallic particles that have higher electrical conductivity than the thermoelectric material and are bonded to and dispersed in the thermoelectric material.
